(19) United States
(12) Patent Application Publication
(10) Pub. No.: US 2009/0321932 A1
(43) Pub. Date: Dec. 31, 2009

(54) Coreless substrate package with symmetric external dielectric layers

(76) Inventors: Javier Soto Gonzalez, Chandler, AZ (US); Tao Wu, Chandler, AZ (US); Pallavi Alur, Chandler, AZ (US); Mihir Roy, Chandler, AZ (US); Sheng Li, Gilbert, AZ (US); Reynaldo Olmedo, Phoenix, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/217,068

(22) Filed: Jun. 30, 2008

(51) Int. Cl. H01L 23/48; H01L 21/4763; H01L 23/52; H01L 21/441; H01L 23/485; H01L 21/44

(52) U.S. Cl. 257/750; 438/622; 438/613; 257/766; 257/774; 257/E21.477; 257/E23.011; 257/E23.021

(57) ABSTRACT

A thin die Package Substrate is described that may be produced using existing chemistry. In one example, a package substrate is built over a support material. A dry film photoresist layer is formed over the package substrate. The support material is removed from the package substrate. The dry film photoresist layer is removed from the substrate and the substrate is finished for use with a package.

### BACKGROUND

1. Field

The present description relates to the field of substrates for use in packaging and mounting semiconductor and micromechanical dies, and in particular to building coreless substrates over a temporary core and then removing the core prior to finishing the substrate.

2. Related Art

Integrated circuits and micromechanical structures are typically formed in groups on a wafer. The wafer is a substrate, typically of silicon or the like and then is cut up into dies, so that each die contains one integrated circuit or micromechanical structure. Each die is then mounted to a substrate and is then typically packaged. The substrate connects the die to a printed circuit board, socket or other connection. The package supports or protect the die and may also provide other functions such as isolation, insulation, thermal control and more.

Substrates for this purpose are typically made of woven glass layers pre-impregnated with an epoxy resin material, such as the prepreg laminate FR-4 commonly used for printed circuit boards. Connection pads and conductive copper traces are then formed on the substrate to provide the interconnection between the die and the system to which it is mounted.

In order to reduce z-height and improve electrical connection, coreless substrates are used. In the coreless substrate, the connection pads and conductive traces are first formed over a core. After these structures have been created, the core upon which the connections are formed is removed. Since a prepreg core may be 800 or more microns thick, removing it can reduce the height of the substrate by more than half. For some coreless technologies a copper core is used rather than a prepreg core.

Creating a coreless substrate, however, presents challenges in providing sufficient structural rigidity and appropriate thermal properties. In addition, there are limitations in forming the layers on the core because only one side of the eventual substrate is accessible. The other side is blocked by the temporary core.

### BRIEF DESCRIPTION OF THE DRAWING FIGURES

FIG. 1 is a diagram of a cross-sectional side view of a coreless substrate attached to a system board and carrying a die according to an embodiment of the present invention;

FIG. 2A is a diagram of a beginning stage in a process for fabricating a coreless substrate in accordance with an embodiment of the present invention;

FIG. 2B is a diagram of a patterning stage in a process for fabricating a coreless substrate in accordance with an embodiment of the present invention;

FIG. 2C is a diagram of a plating stage in a process for fabricating a coreless substrate in accordance with an embodiment of the present invention;

FIG. 2D is a diagram of a stripping stage in a process for fabricating a coreless substrate in accordance with an embodiment of the present invention;

FIG. 2E is a diagram of a layering stage in a process for fabricating a coreless substrate in accordance with an embodiment of the present invention;

FIG. 2F is a diagram of a via drilling stage in a process for fabricating a coreless substrate in accordance with an embodiment of the present invention;

FIG. 2G is a diagram of a electroless plating stage in a process for fabricating a coreless substrate in accordance with an embodiment of the present invention;

FIG. 2H is a diagram of a patterning stage in a process for fabricating a coreless substrate in accordance with an embodiment of the present invention;

FIG. 2I is a diagram of a plating stage in a process for fabricating a coreless substrate in accordance with an embodiment of the present invention;

FIG. 2J is a diagram of an etching stage in a process for fabricating a coreless substrate in accordance with an embodiment of the present invention;

FIG. 2K is a diagram of a layering stage in a process for fabricating a coreless substrate in accordance with an embodiment of the present invention;

FIG. 2L is a diagram of a layering stage in a process for fabricating a coreless substrate in accordance with an embodiment of the present invention;

FIG. 2M is a diagram of a patterning stage in a process for fabricating a coreless substrate in accordance with an embodiment of the present invention;

FIG. 2N is a diagram of a DFR laminating stage in a process for fabricating a coreless substrate in accordance with an embodiment of the present invention;

FIG. 2O is a diagram of a core separation stage in a process for fabricating a coreless substrate in accordance with an embodiment of the present invention;

FIG. 2P is a diagram of a DFR stripping stage in a process for fabricating a coreless substrate in accordance with an embodiment of the present invention;

FIG. 2Q is a diagram of a SR coating stage in a process for fabricating a coreless substrate in accordance with an embodiment of the present invention;

FIG. 2R is a diagram of a metal coating stage in a process for fabricating a coreless substrate in accordance with an embodiment of the present invention'

FIG. 2S is a diagram of a presolder stage in a process for fabricating a coreless substrate in accordance with an embodiment of the present invention;

FIG. 2A is a diagram of a beginning stage in a process for fabricating a coreless substrate in accordance with an embodiment of the present invention'

FIG. 3 is a diagram of a cross-sectional side view of a temporary core with coreless substrates formed on either side according to an embodiment of the present invention; and

FIG. 4 is a diagram of a cross-sectional side view of a coreless substrate formed on one side of a temporary core according to an embodiment of the present invention.

### DETAILED DESCRIPTION

According to an embodiment of the invention, a protective step is used to separate a coreless substrate from the temporary core before the substrate is submitted to a SR (Solder Resist) process. Once separated, thin package SR may be used to transform the BE (Back End) of a coreless substrate to a standard building FCBGA (Flip Chip Ball Grid Array) process. This allows many conventional chemistry and processing steps to be used. It also allows coreless substrates routing to be formed on both sides of the substrate.

It may be difficult to produce coreless packages using existing materials. Some processes have been proposed which require new surface chemistry. A new surface chemistry imposes new capital investments for substrate suppliers, for developing experience and consistency, and for creating the surface finishes between top and bottom layers.

According to an embodiment of the invention, the assembly process may use a very similar external SR layer to substrates with cores. This simplifies the manufacture and also the integration of coreless packages and those with cores into larger systems. Such a single surface finish chemistry allows for better shock performance and minimizes assembly transparency issues. According to an embodiment of the invention, Ni (Nickel) may be used as a barrier for a Cu (Copper) chemical etch.

According to an embodiment of the invention the inner side of a package formed with a coreless substrate will have a thicker Ni layer. In one example, the Ni layer is approximately one hundred times and at least ten times thicker than the adjacent layers, for example Pd and Au. The thicker Ni layer may also have a different grain structure. In addition, as described below, SR may be formed on both sides of the substrate rather than on only one side. In other words, a dual side SR may be produced for coreless ultra thin packages.

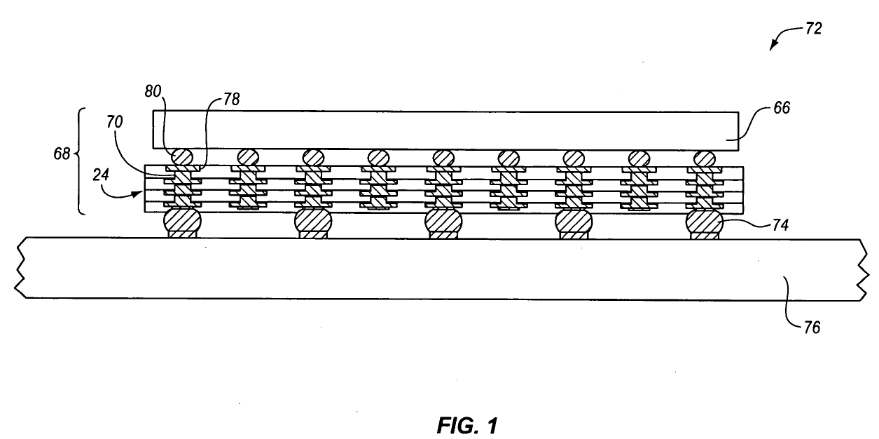

Referring to FIG. 1, a portion of an electronics system 72 is shown. The system may be a computer, a portable information manager, a wireless device, an entertainment system, a portable telephone or communications manager, or any of a variety of other electronics systems. In the illustrated example a package 68 is soldered to a motherboard 76, or any other system or logic board. The package is attached with solder balls 74 or any other type of attachment system may be used including a socket or other fixture. The motherboard supplies power, control, and data connections between the package and other components of the electronics system 72.

The illustrated package is an ultra thin package with a coreless substrate. In this example, the package 68 has a die 66, containing the electronic or micromechanical system, attached to a coreless substrate 24. The coreless substrate has solder balls 74 opposite the die for attachment to the motherboard 76.

As shown, the die 66 attaches to the substrate 24 with a ball grid array 80 through a series of contact pads 78. The contacts 78 lead to vias 70 that conduct through to the solder balls 74. The coreless substrate 24 may include a network of Cu traces (not shown) that run horizontally to connect vias 70 to each other. The particular number of pads and solder balls and the connections between them may be adapted to suit any particular implementation.

The package may also include additional components (not shown) such as a cover, a heat spreader, a cooling device, such as fins, liquid cooling contacts and other components. The package may also include additional dies, external connection ports, and additional contacts on the top or sides of the package. A wide variety of additional structures may be added or adapted to the package, depending on the particular implementation.

As mentioned above, the package may also be adapted for use with a socket (not shown) or other receptacle. The package may accordingly include clamping surfaces, retention features and conductive connectors to features on the socket.

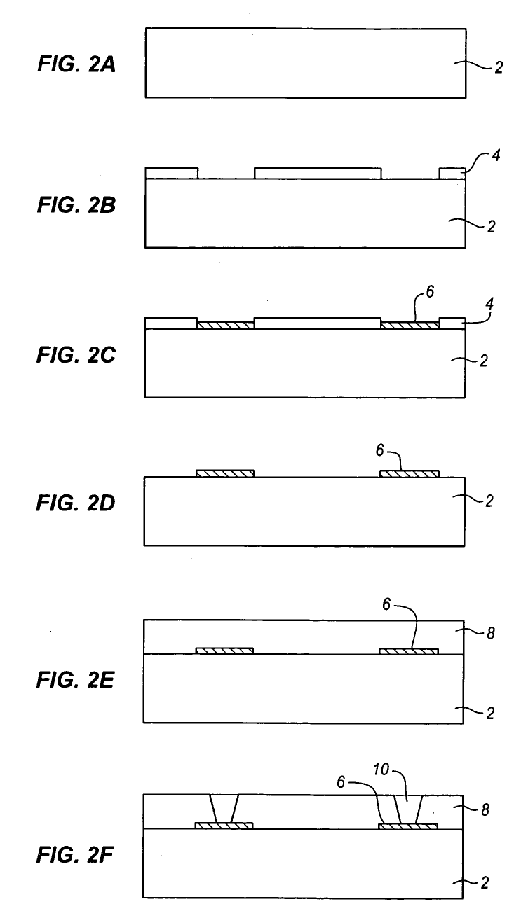

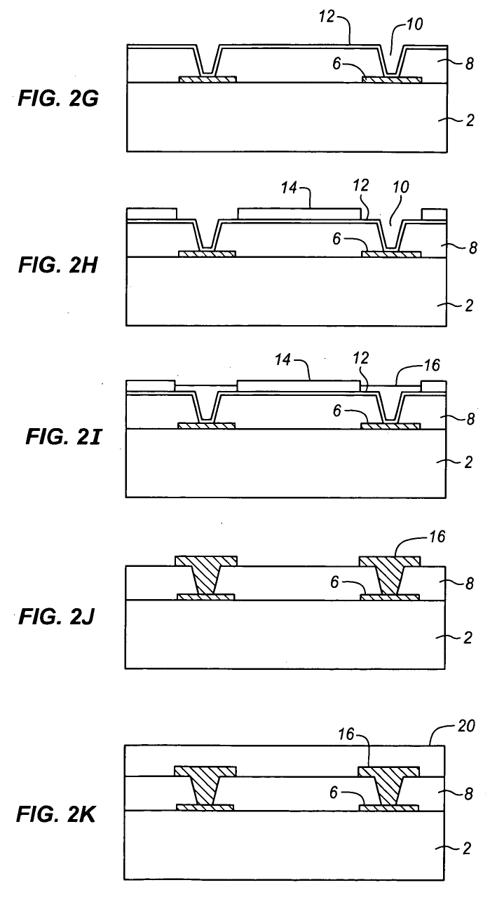

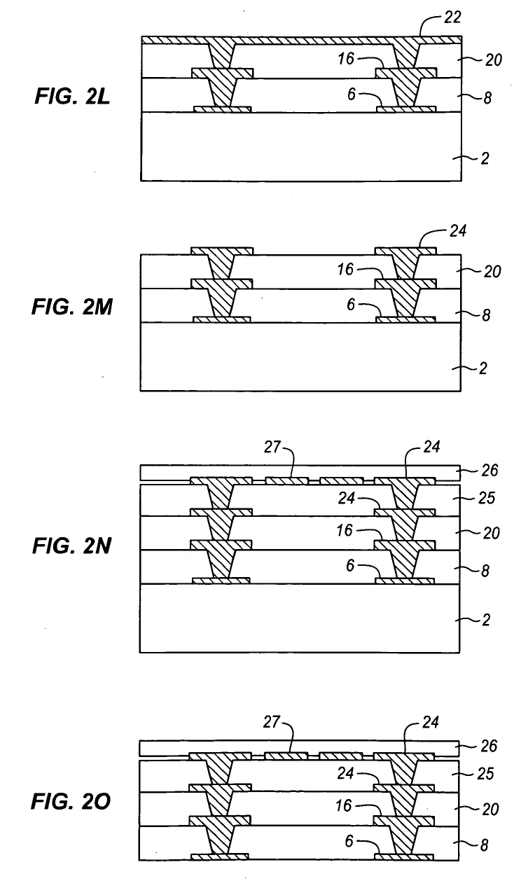

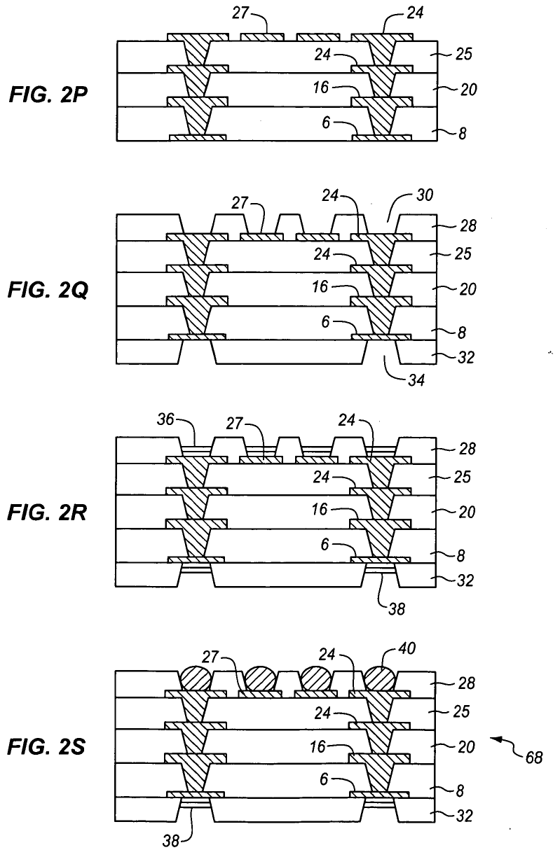

Referring to FIG. 2A, a process for fabricating a coreless substrate 68 begins with a temporary core 2. The temporary core may be made of a variety of different materials. The materials may be selected for the ease of building the layers of the substrate and the ease of removing the temporary core. In the present example, the core is a sheet of copper about 800 microns thick. Other possible material include silicon and prepreg laminates, such as FR-4. FIG. 2A is a cross-sectional side view of the core.

In FIG. 2B, a patterned layer of photoresist 4 is applied to the top surface of the temporary core 2. The photoresist layer has lands with gaps in between the lands. In the described example layers are applied only to the top surface of the temporary core. However, similar or the same processing steps may also be applied to the bottom surface of the temporary core at the same time. The doubles the yield for each production cycle. In addition, the figures show only a single substrate, while in actual production, many substrates may be produced side-by-side and simultaneously on a single temporary core.

In FIG. 2C, an electrolytic metal plating 6 is applied over the photoresist 4. This produces contact surfaces in the gaps between the lands. The particular metal may be selected based on the particular implementation. Materials other than metal may also be selected. In one example it is formed as an electrolytic plating first of Cu, then Ni, then Cu again. This is a simpler, faster less expensive process than, for example a Ni, Pd (Palladium), Au (Gold) process or a Cu, Au, Pd, Ni, Cu process commonly in use. It also produces better electrical, thermal, and mechanical characteristics.

In FIG. 2D, the photoresist is stripped, leaving the metallic contacts 6.

In FIG. 2E, an insulator layer 8 of build up film, such as an epoxy/phenol novolac resin, or other material is applied over the metallic contacts 6. The insulator, which also acts as a filler, provides the physical structure of the substrate after the core is removed and may be made of a variety of insulating materials, with appropriate thermal and mechanical characteristics. Polymers, silicon-based materials and plastic resins with silica insulators may be used, among others.

In FIG. 2F vias 10 are drilled through the insulator layer 8 using laser drilling. The vias may be produced in a variety of other ways as desired. As shown in the figure, the vias extend from the top of the insulator layer through the insulator layer to the metal contacts 6.

In FIG. 2G, an electroless Cu layer 12 is applied over the insulator layer and the vias.

FIG. 2H, shows the start of another layer similar to that created in FIGS. 2B to 2G. The additional layer allows for conductive patterning to connect vias to each other or isolate them from each other. It also allows for a thicker stronger coreless substrate to be produced. In FIG. 2H another layer 14 of photoresist is applied over the structure. In this example, the photoresist is shown as being applied between the vias.

In FIG. 2I, the top surface of the substrate is plated 16 with a Cu/Ni/Cu process to fill the vias and any other areas between the photoresist.

In FIG. 2J, the photoresist is flash etched, leaving the filled vias and contact pads at the top of each via. These contact pads may be in the form of copper traces between vias as mentioned above.

In FIG. 2K, another insulator layer 20 is laminated over the top of the substrate.

In FIG. 2L, the insulator is drilled as in FIG. 2F and plated as in FIGS. 2F and 2G to form a second level of filled conductive vias 22 through the second insulator layer 20.

In FIG. 2M, appropriate patterning 24 is formed at the top of the second layer of vias as in FIGS. 2H, 2I, and 2J.

In FIG. 2N, a third layer 25 may be built up in a manner similar to the first and second layers. Additional layers may be added depending on the particular implementation in order to meet physical, electrical, and thermal needs. The top of the top layer is then laminated with a DFR (Dry Film Resist) 26. This photoresist layer protects the top of the substrate when the temporary core is removed.

In addition, FIG. 2N shows that additional metallic contact areas 27 have been added over the third insulator layer 25. The additional contacts are provided as examples In the cross-sectional side views of the present examples the electrical pathways between the contacts are not visible. However, the additional contacts 27 allow for a variety of different electrical connections to be made between the vias and between different conductors on the die or motherboard.

In FIG. 2O, the temporary core is separated from the substrate. This creates pockets at the contact pads 6 in the bottom surface of the substrate which may serve as connections or attachment points on the substrate. The pockets are aligned with the vias 10 that were drilled over them in FIG. 2F.

The figures above describe an example of manufacturing a coreless substrate 68. The number of layers may be modified to suit any particular implementation. After the top layer Cu plating, DFR lamination 26 may be used as a protective layer. This allows the temporary core 2 to be separated using electrolytic Ni as a Cu etching barrier.

The DFR 26 may then be stripped as shown in FIG. 2P then SR (Solder Resist) coating 28, 32 may be applied to at both sides of the substrate as shown in FIG. 2Q.

The exposed metal surfaces 27, 34 may then be finished with, for example, an electroless Ni/Pd/Au coating 36, 38. as shown in FIG. 2R. However, a variety of different materials may be used. In this example, a thick layer of Ni is followed by Pd plating and then Au plating. The Ni layer may be one hundred times thicker than the other layers.

In FIG. 2P, the DFR layer 26 is stripped or etched off, revealing the previously protected contact pads 24 below.

Finally, at FIG. 2S, presolder 40 is applied to the upper plated contact areas between the solder resist. In the present example, the bottom contacts are not further processed. The presolder may be used for C4 (Controlled Collapse Chip Connection) pads and as mentioned with respect to FIG. 2O, interconnections or routing may be done with Cu or other electrolytic plating at the C4 pad layer.

As an alternative SR printing may be performed on both sides either with or without the surface finish 36, 38.

As another alternative after the core separation (FIG. 2O), a dry film type SR lamination may be applied to the bottom side.

As another alternative, instead of a DFR lamination PET (Poly Ethylene Terephthalate) lamination may be used. The PET lamination may be applied after the top layer Cu plating. The PET lamination serves as a protective layer during core separation. Electrolytic Ni may still function as a Cu etching barrier. The PET lamination may then be removed. SR coating may be applied to one or both sides and the surface finish electroless Ni/Pd/Au layer may be applied as shown in the figures. While in the present example, the SR metal layer may be formed from a variety of different materials. This Ni/Pd/Au layer may be a thick layer of Ni is followed by Pd plating and then Au plating.”

As shown in the Figures, SR may be used to cover the substrate's insulator lamination even with different types of contacts. On the top side of the substrate of FIG. 2S, C4 (Controlled Collapse Chip Connection) pads are used. The insulator lamination is between the pads, but the SR covers the insulator layer. On the other hand, the bottom side of the structure is adapted for use with a BGA (Ball Grid Array). As shown SR also covers the insulator on the BGA side.

The SR protection on the bottom side also allows for connections on the bottom surface to be routed within the substrate. As shown in FIG. 2D, the bottom side is initiated with the plating of the metal pads 6 directly into the temporary core 2. This leads to metal defined pads, so there is no overlap of the external layer and the metal pads. This characteristic may degrade the substrate's mechanical strength by reducing the fracture area near the bottom side.

Since this layer is typically exposed to the environment in the finished substrate, routing cannot readily be used on the inner layer. Any routing may be unreliable. By applying the SR layer 32 over the bottom side as shown in FIG. 2Q, routing may be patterned onto both the top and bottom sides without any risk from the environment.

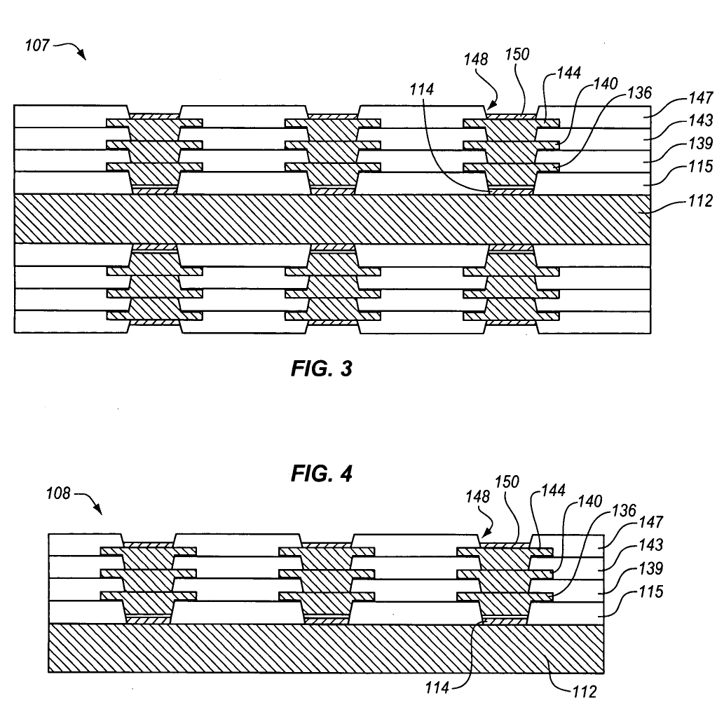

FIG. 3 shows an example of producing two substrates simultaneously, one on either side of a temporary core. In FIG. 3, at the center of the structure 107 is a temporary core 112 that has been patterned with connection pads 114. Three layers of insulator 115, 139, and 143 have been laminated over these connection pads with vias 136, 140, 144 drilled through each layer to form a connection from the external side of the substrate to the internal temporary core. FIG. 3 also shows contact pads 150 on the external layers with a protective SR layer 147 between the contact pads.

The top and bottom substrate structures are identical in FIG. 3 showing that applying the same processes to both sides simultaneously results in virtually identical structures on either side of the copper core. The precise nature of the further processing may be adapted to suit different implementations.

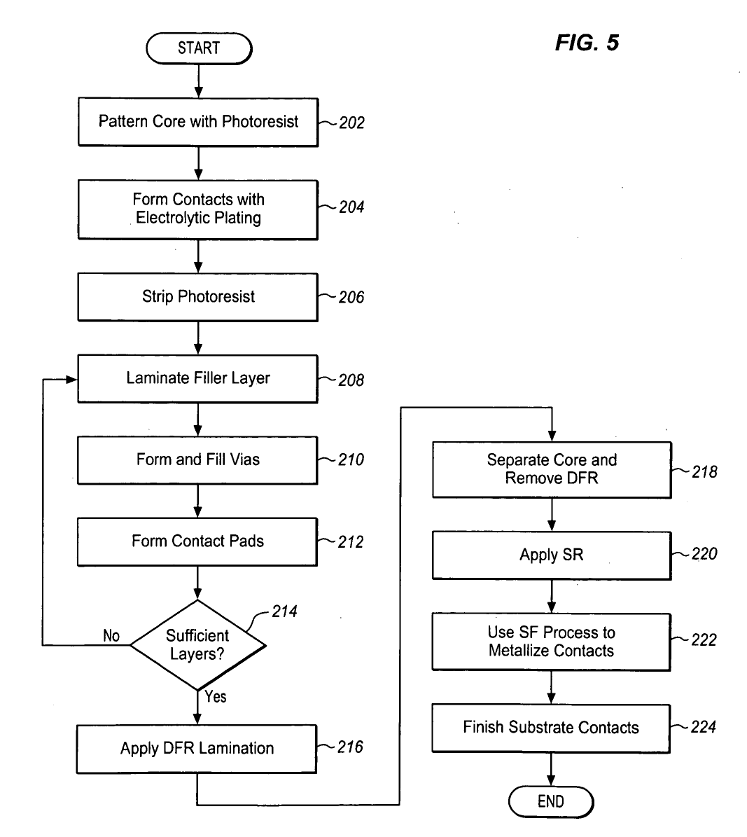

FIG. 4 shows a substrate fabrication structure 108 in a similar condition. However, in the example of FIG. 4, a substrate is being built up on only one side of the temporary core. Such an approach may be preferred for certain processing and fabrication equipment or designs. In FIG. 4, the same reference numerals are used as in FIG. 3 and the corresponding elements are the same.

FIGS. 3 and 4 suggest an intermediate condition between FIG. 2M and FIG. 2N. This suggests possible variations in the sequence suggested in these figures. In FIGS. 3 and 4, the SR process and the SF layer is applied before the temporary core is removed, unlike in FIGS. 2O, P, Q, and R. This results in the FIGS. 3 and 4 structure. For subsequent processing, the DFR lamination is applied over the FIGS. 3 and 4 structure, the core is separated, the DFR stripped, and then the contact pads or connections are finished.

FIG. 5 shows the operations described in the context of FIGS. 2A to 2S as a process flow diagram. The operations begin with the temporary core, made of Cu, prepreg or any other suitable material. At block 202, the core is patterned with photoresist for creating the connection points that will be at the bottom of the eventual substrate. At block 204, the electrical connection points are formed. In the examples above, this is done using electrolytic plating of Cu, then Ni, then Cu. At block 206, the photoresist is stripped, leaving the contact pads.

At block 208, the first layer of insulator is laminated over the contact pads. This begins the formation of the portion that will eventually form the structure of the substrate. At block 210, the conductive vias through the insulator down to the contact pads are formed. This is done by first laser drilling and then coating with copper, or any other appropriate conductor. At block 212, contact pads are formed over the vias by patterning, filling with copper and then etching.

At block 214, the process returns to block 208 until sufficient layers have been formed. In brief, the lamination and formation of vias is repeated to form the desired number of additional layers of substrate. This thickens and strengthens the substrate to later support the die.

At block 216, a DFR lamination is applied to the structure to protect the vias and contact pads. Then at block 218, the temporary core is separated from the substrate and the DFR is stripped off.

At block 220, SR is applied and patterned to create openings for the contact pads. At block 222, the contact pads are formed by an SF process using Ni, then Pd, then Au. Finally, the contact pads are finished at block 224 with the appropriate surfaces, such as solder balls for a C4 pad. Optionally, additional finishing steps may be used for the opposite side, the side that was formally attached to the temporary core.

The finished substrate may then be attached to one or more dies. Leads and other components may be attached, if desired. The resulting structure may then be used to form a package as suggested in FIG. 1.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations are described as multiple discrete operations to aid in understanding the description. However, the order of description should not be construed to imply that these operations are necessarily order dependent. In particular, these operations need not be performed in the order of presentation. Operations described may be performed in a different order than the described embodiment. Various additional operations may be performed and described operations may be omitted.

Many modifications and variations are possible in light of the above teachings. Various equivalent combinations and substitutions may be made for various components and operations shown in the figures. The scope of the invention is not to be limited by this detailed description, but rather by the claims appended hereto.

The example cleaning processes described above are provided only as examples. There may be other and different chemical processes that break down, convert to gas or otherwise eliminate photo-induced defects on a mask. The example above show how combinations of illumination, heat, and exposure to gases such as air, oxygen, and water vapor may partially or completely eliminate these compounds and reduce the amount of or completely eliminate a wide range of different types of photo-induced defects from a photomask surface. The particular combination of illumination, heat, vacuum and other parameters may be selected with the above examples in mind. Alternatively, the particular combination may be selected based on the parameters described above and then optimized using trial and error.

A lesser or more complex cleaning chamber, set of cleaning operations, photomask, and pellicle may be used than those shown and described herein. Therefore, the configurations may vary from implementation to implementation depending upon numerous factors, such as price constraints, performance requirements, technological improvements, or other circumstances. Embodiments of the invention may also be applied to other types of photolithography systems that use different materials and devices (e.g. EUV lithography) than those shown and described herein. While the description above refers primarily to 193 nm photolithography equipment and techniques, the invention is not so limited and may be applied to a wide range of other wavelengths and other process parameters. In addition, the invention may be applied to the production of semiconductors, microelectronics, micromachines and other devices that use photolithography technology.

In the description above, numerous specific details are set forth. However, it is understood that embodiments of the invention may be practiced without these specific details. For example, well-known equivalent materials may be substituted in place of those described herein, and similarly, well-known equivalent techniques may be substituted in place of the particular processing techniques disclosed. In addition, steps and operations may be removed or added to the operations described to improve results or add additional functions. In other instances, well-known circuits, structures and techniques have not been shown in detail to avoid obscuring the understanding of this description.

While the embodiments of the invention have been described in terms of several examples, those skilled in the art may recognize that the invention is not limited to the embodiments described, but may be practiced with modification and alteration within the spirit and scope of the appended claims. The description is thus to be regarded as illustrative instead of limiting.

1. A method comprising:
building a package substrate over a support material;
forming a dry film photoresist layer over the package substrate;
removing the support material from the package substrate;
removing the dry film photoresist layer; and
finishing the substrate for use with a package.

2. The method of claim 1 wherein finishing the substrate comprises:
applying a solder photoresist to the substrate; and
applying a metal layer using an SF process.

3. The method of claim 2, wherein applying a metal layer comprises applying a Ni layer, then a Pd layer, then a Au layer.

4. The method of claim 3, wherein the Ni layer is thicker than the Pd layer and the Au layer.

5. The method of claim 4, wherein the Ni layer is at least ten times thicker than the Pd layer.

6. The method of claim 2, wherein finishing the substrate further comprises applying solder balls to at least a portion of the metal layer.

7. The method of claim 1, wherein building a package substrate comprises:
plating a metal pattern directly on the support material; and
applying a insulator over the metal pattern.

8. The method of claim 7, wherein plating a metal pattern comprises applying a series of metal layers to the support material electrolytically.

9. The method of claim 8, wherein the series of metal layer comprises Cu, then Ni, then Cu.

10. The method of claim 7, wherein plating a metal pattern comprises:
patterning a photoresist directly on the support material;
using the photoresist pattern to define the metal pattern during electrolytic plating; and
stripping the photoresist.

11. The method of claim 7, wherein plating a metal pattern comprises applying a layer of Cu directly over the support material electrolytically.

12. The method of claim 11, wherein the support material is a Cu panel.

13. A package substrate comprising:
a plurality of insulator layers formed by sequential lamination;
a plurality of contacts formed by plating contacts onto a support material, covering the contacts with a dry film photoresist layer, removing the support material, removing the dry film photoresist and finishing the contacts.

14. The package substrate of claim 13, further comprising vias drilled through the insulator layers to connect with at least one contact.

15. The package substrate of claim 14, further comprising solder resist connectors opposite the plurality of contacts formed over the vias after the support material is removed.

16. The package substrate of claim 13, wherein the substrate is finished by applying a solder photoresist to the substrate, and applying a metal layer using an SF process.

17. The package substrate of claim 13, wherein plating contacts onto the support material comprises applying a Ni layer, then a Pd layer, then a Au layer.

18. The package substrate of claim 17, wherein the Ni layer is thicker than the Pd layer and the Au layer.

19. The package substrate of claim 13, wherein plating contacts on to the support material comprises:
patterning a photoresist directly on the temporary core;
using the photoresist pattern to define the metal pattern during electrolytic plating; and
stripping the photoresist.

20. The package substrate of claim 19, wherein plating a metal pattern comprises applying a layer of Cu directly over the support material electrolytically.
